(19) United States
(12) Patent Application Publication
(10) Pub. No.: US 2014/0124949 A1
(43) Pub. Date: May 8, 2014

(54) SEMICONDUCTOR DEVICE AND METHOD OF MANUFACTURING SEMICONDUCTOR DEVICE

(71) Applicants: Jong Sik Paek, Gyeonggi-do (KR); Doo Hyun Park, Gyeonggi-do (KR)

(72) Inventors: Jong Sik Paek, Gyeonggi-do (KR); Doo Hyun Park, Gyeonggi-do (KR)

(21) Appl. No.: 13/753,120

(22) Filed: Jan. 29, 2013

(30) Foreign Application Priority Data
Nov. 6, 2012 (KR) 10-2012-0125070

(51) Int. Cl. H01L 23/498; H01L 21/50

(52) U.S. Cl. CPC H01L 23/49827; H01L 21/50; H01L 22/14
USPC 257/774; 438/126; 438/15

(57) ABSTRACT

Provided are a semiconductor device and a method of manufacturing the same. The method may, for example, comprise forming an interposer on a dummy substrate; forming a conductive pillar on the interposer; contacting the top of the interposer with at least one semiconductor die; encapsulating the conductive pillar and the at least one semiconductor die with an encapsulant; forming a redistribution layer that is electrically connected to the conductive pillar, on the semiconductor die; removing the dummy substrate from the interposer; attaching the interposer, which has the at least one semiconductor die in contact, to a substrate and testing the at least one semiconductor die; and contacting a stacked semiconductor device with the redistribution layer.

### CROSS-REFERENCE TO RELATED APPLICATIONS/INCORPORATION BY REFERENCE

The present application makes reference to, claims priority to, and claims the benefit of Korean Patent Application No. 10-2012-0125070, filed on Nov. 6, 2012, the contents of which are hereby incorporated herein by reference, in their entirety.

### FIELD OF THE INVENTION

The present invention relates to a semiconductor device and a method of manufacturing the same.

### BACKGROUND OF THE INVENTION

In general, a semiconductor device in which a semiconductor die is mounted on an interposer and then the interposer is stacked upon another semiconductor die or substrate is called a 2.5D package. Typically, a 3D package refers to a package where a semiconductor die is directly stacked on another semiconductor die or substrate without an interposer.

In such an arrangement, the semiconductor package is formed of a plurality of stacked semiconductor die, and if one semiconductor die is defective, the remaining stacked semiconductor die become useless. Accordingly, the cost of the loss of the entire semiconductor package and its semiconductor die occurs.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A semiconductor device and method of manufacturing a semiconductor device, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a sectional view of an exemplary semiconductor device, in accordance with a representative embodiment of the present invention.

FIG. 2 is a sectional view of an exemplary semiconductor device, in accordance with another representative embodiment of the present invention.

FIG. 3 is a sectional view of an exemplary semiconductor device, in accordance with yet another representative embodiment of the present invention.

FIGS. 4A to 4G are sequential selection views illustrating an exemplary method of manufacturing a semiconductor device, in accordance with a representative embodiment of the present invention.

FIGS. 5A to 5G are sequential selection views illustrating an exemplary method of manufacturing a semiconductor device, in accordance with a representative embodiment of the present invention.

### DETAILED DESCRIPTION OF THE INVENTION

Aspects of the present invention relate to a semiconductor device and a method of manufacturing the same. More specifically, representative embodiments of the present invention may relate to a semiconductor device and a method of manufacturing such a semiconductor device, where the semiconductor device includes a plurality of semiconductor die, in which the manner of manufacture reduces costs by preventing the loss of other semiconductor die due to one or more defective semiconductor die.

Various aspects of the invention will be described in more detail with reference to the accompanying drawings. In such a manner, those skilled in the art will easily realize various aspects of the present invention upon reading the present patent application.

It should be noted that the thickness or size of each layer may be exaggerated for clarity in the accompanying drawings, and that like reference numerals may refer to like elements. Additionally, the term “semiconductor die” in this specification includes, for example, a semiconductor chip having an active circuit and/or a passive circuit, a semiconductor wafer, or equivalents thereof.

As utilized herein, the term “exemplary” means serving as a non-limiting example, instance, or illustration. Also, as utilized herein, the term “representative” means serving as a non-limiting example, instance, or illustration.

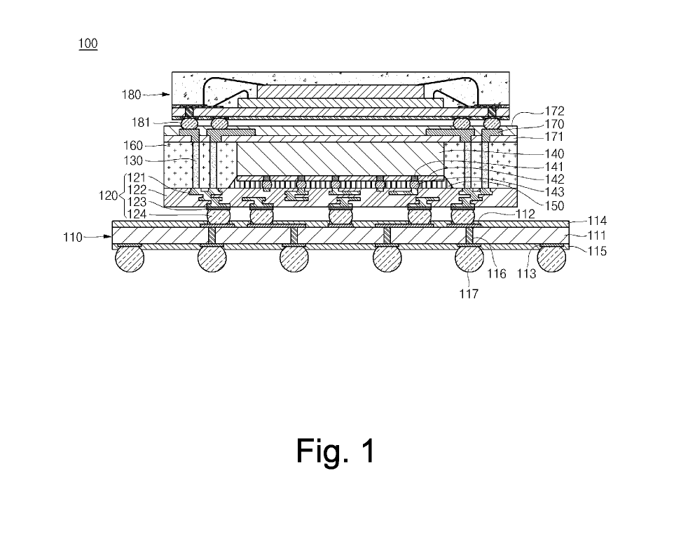

FIG. 1 is a sectional view of an exemplary semiconductor device 100, in accordance with a representative embodiment of the present invention.

Referring to the example of FIG. 1, the semiconductor device 100 includes a substrate 110, an interposer 120, one or more conductive pillars 130, a semiconductor die 140, an underfill 150, an encapsulant 160, a redistribution layer 170, and a stacked semiconductor device 180.

The substrate 110 includes an insulating layer 111, a first circuit pattern 112 on the top of the insulating layer 111, a second circuit pattern 113 on the bottom of the insulating layer 111, a first passivation layer 114 covering the outer circumference of the first circuit pattern 112, a second passivation layer 115 covering the outer circumference of the second circuit pattern 113, and a conductive via 116 electrically connecting the first circuit pattern 112 and the second circuit pattern 113 and penetrating the insulating layer 111. In the example embodiment of FIG. 1, the substrate 110 further includes a solder ball 117 welded onto the second circuit pattern 113. In a representative embodiment of the present invention, the solder ball 117 may connect the substrate 110 to an outer circuit.

In the example illustrated in FIG. 1, the interposer 120 may be formed on the substrate 110, and may be electrically connected to the first circuit pattern 112 of the substrate 110. In the example of FIG. 1, the interposer 120 includes an internal redistribution layer 121 and a dielectric layer 122. In a representative embodiment of the present invention, in relation to the interposer 120, the internal redistribution layer 121 of a multi-layered structure may be formed and the internal redistribution layer 121 may then be protected by the dielectric layer 122. In the example of FIG. 1, the internal redistribution layer 121 is exposed to the top and bottom of the dielectric layer 122. Furthermore, the internal redistribution layer 121 on the top and the bottom of the dielectric layer 122 may be formed with a relatively large width for easy bumping later. Such a portion having a relatively large width may be defined as a pad or a land. Additionally, an under bump metal 123 may be formed on the internal redistribution layer 121 exposed at the bottom of the interposer 120 and a bump 124 may be formed on the under bump metal 123, so that the interposer 120 may be electrically connected to the substrate 110.

In a representative embodiment of the present invention, an internal redistribution layer such as the internal redistribution layer 121 of FIG. 1 may be formed of one selected from materials such as, for example, copper, aluminum, or suitable equivalents or combinations thereof. Additionally, a dielectric layer such as the dielectric layer 122 of FIG. 1 may be formed of, for example, one selected from a silicon oxide layer, a silicon nitride layer, a polymer layer, and suitable equivalents or combinations thereof. It should be noted, however, that the present invention is not limited to such materials, and that other suitable materials may be employed.

In a representative embodiment of the present invention, conductive pillars such as the one or more conductive pillars 130 of FIG. 1 may be formed on the internal redistribution layer 121 and may be exposed to the top of the interposer 120. The one or more conductive pillars 130 may be formed on a portion of the internal redistribution layer 121 exposed to the top of the interposer 120 and may have a pillar form. In one representative embodiment of the present invention, the one or more conductive pillars 130 may be formed on the internal redistribution layer 121 at one side or near the edge of the interposer 120, in order to allow the semiconductor die 140 to efficiently contact the interposer 120. In another representative embodiment, the one or more conductive pillars 130 may be formed at or near the middle of the interposer 120. A conductive pillar such as the one or more conductive pillars 130 of FIG. 1 may, for example, be formed with the same height as the semiconductor die 140, so that it may be electrically connected to the stacked semiconductor device 180 stacked on the semiconductor die 140. In a representative embodiment of the present invention, a conductive pillar such as the one or more conductive pillars 130 of FIG. 1 serve to connect the semiconductor die 140 and the stacked semiconductor device 180 (e.g., a semiconductor die, a subassembly comprising one or more semiconductor die, etc.), and/or the stacked semiconductor device 180 and the substrate 110, through the interposer 120. In some representative embodiments of the present invention, the one or more conductive pillars 130 may be formed of a copper pillar, but it should be noted that the present invention is not necessarily so limited, but may employ other suitable materials without departing from the spirit and scope of the present invention.

In a representative embodiment of the present invention, a semiconductor die such as the semiconductor die 140 of FIG. 1 may be formed of a silicon material and may include a plurality of semiconductor devices formed therein. As shown in FIG. 1, the semiconductor die 140 sits on the top of the interposer 120, so that the semiconductor die 140 is electrically connected to the interposer 120. Although only one semiconductor die 140 is shown in the illustration of FIG. 1, that does not necessarily represent a specific limitation of the present invention, unless explicitly recited in the claims, as a greater number of semiconductor die such as semiconductor die 140 may sit on an interposer such as the interposer 120, without departing from the spirit and scope of the present invention. The semiconductor die 140 may have a flat top surface and a flat bottom surface facing the top surface. A plurality of bond pads 141 may be formed on the bottom surface of the semiconductor die 140, and a protective layer 142 may be formed on the outer circumference of the bond pad 141. In a representative embodiment of the present invention, a plurality of bumps 143 may be formed on the bond pad 141 and may be electrically connected to the internal redistribution layer 121 exposed at the top of the interposer 120. The semiconductor die 140 including the plurality of bumps 143 may be placed on the interposer 120, and the semiconductor die 140 may be electrically connected to the internal redistribution layer 121 of the interposer 120 by melting the bump 143. That is, the semiconductor die 140 and the interposer 120 may be electrically connected to one another through the plurality of bumps 143. Moreover, in a representative embodiment of the present invention, a semiconductor die such as the semiconductor die 140 of FIG. 1 may be electrically connected to an internal redistribution layer, such as the internal redistribution layer 121 of FIG. 1, at a portion where a conductive pillar such as the one or more conductive pillars 130 is not formed. For example, the semiconductor die 140 may be positioned at the inside of the one or more conductive pillars 130. The semiconductor die 140 may be, for example, one or more of a memory device, a Graphics Processing Unit (GPU), a Central Processing Unit (CPU), and/or suitable equivalents thereof. It should be noted, however, that a representative embodiment of the present invention is not necessarily limited to such device types, and that other types of semiconductor devices may be employed without departing from the spirit and scope of the present invention.

In a representative embodiment of the present invention, a material such as, for example, the underfill 150 of FIG. 1 may be placed or formed between the interposer 120 and the semiconductor die 140. In one representative embodiment of the present invention, the underfill 150 may cover the lateral bottom of the semiconductor die 140 in addition to being between the interposer 120 and the semiconductor die 140. An underfill such as the underfill 150 of FIG. 1 may be used to improve the physical/mechanical adhesion between the interposer 120 and the semiconductor die 140, and to prevent the separation of the interposer 120 and the semiconductor die 140 that may result due to stress resulting from a difference in the thermal expansion coefficient of the interposer 120 and the semiconductor die 140.

As shown in the illustration of FIG. 1, the encapsulant 160 may be used to cover one or more conductive pillars such as the one or more conductive pillars 130, and one or more semiconductor die such as the semiconductor die 140 on the interposer 120, for example in order to protect them from an external environment. In some representative embodiments of the present invention, the encapsulant 160 may cover the surfaces of the one or more conductive pillars 130, the semiconductor die 140, and the underfill 160, and may expose the tops of one or more conductive pillars, such as the one or more conductive pillars 130, and the semiconductor die 140, to the external environment. In a representative embodiment of the present invention, one or more structures such as the one or more conductive pillars 130 may be electrically connected to the stacked semiconductor device 180, so that the heat radiation performance of the semiconductor die 140 may be improved. In the example of FIG. 1, the one or more conductive pillars 130, the semiconductor die 140, and encapsulant 160 have the same height top surface. In a representative embodiment of the present invention, the encapsulant 160 may be an electrical insulating material, and may, for example, be formed of an epoxy based resin or other suitable material. It should be noted that a representative embodiment of the present invention may include a greater or lesser number of structures such as the one or more conductive pillars 130, depending on the nature of the semiconductor device(s) employed, without departing from the spirit and scope of the present invention.

In a representative embodiment of the present invention, a redistribution layer such as the redistribution layer 170 of FIG. 1 may be formed on an encapsulate material such as the encapsulant 160, and may be electrically connected to one or more conductive pillars such as the one or more conductive pillars 130. The redistribution layer 170 may be extend from the top of the one or more conductive pillars 130 to the top of the semiconductor die 140. A redistribution layer such as the redistribution layer 170 of FIG. 1 may be formed between the semiconductor die 140 and the stacked semiconductor device 180, and may electrically connect the semiconductor die 140 and the stacked semiconductor device 180 through one or more structures such as the conductive pillar 130.

In a representative embodiment of the present invention, before a redistribution layer such as the redistribution layer 170 is formed on the encapsulant 160, a lower passivation layer 171 may be formed on the encapsulant 160 to expose the one or more conductive pillars 130. In some representative embodiments of the present invention, elements of a redistribution layer such as the redistribution layer 170 may be formed on a passivation layer such as the lower passivation layer 171, and may be electrically connected to one or more corresponding structures such as the one or more conductive pillars 130. In addition, a passivation layer such as the upper passivation layer 172 may be formed on the lower passivation layer 171, in order to cover the redistribution layer 170. In this way, the upper passivation layer 172 of a representative embodiment of the present invention may expose a portion of the redistribution layer 170 to the external environment.

As shown in the example of FIG. 1, in a representative embodiment of the present invention, a first semiconductor device such as the stacked semiconductor device 180 may sit upon a second semiconductor device such as the semiconductor die 140, and may be electrically connected to a structure such as the redistribution layer 170. In such an arrangement, the stacked semiconductor device 180 may be electrically connected to the redistribution layer 170 through the use of an interconnection such as, for example, the solder ball 181. In some representative embodiments of the present invention, the stacked semiconductor device 180 may be electrically connected to the semiconductor die 140 and/or the substrate 110 through the redistribution layer 170, the one or more conductive pillars 130, and the interposer 120. In a semiconductor device in accordance with a representative embodiment of the present invention, a stacked semiconductor die, such as the stacked semiconductor device 180 of FIG. 1, may include a plurality of semiconductor die that may be staked and connected through one or more conductive wires. Accordingly, it should be noted that a stacked semiconductor device such as the stacked semiconductor device 180 is not specifically limited to the arrangement shown in the example illustrated in FIG. 1, unless explicitly recited in the claims, and may include a greater or lesser number of the described structures and semiconductor die, without departing from the spirit or scope of the present invention. That is, if the stacked semiconductor device 180 is a semiconductor device that is able to be stacked on the semiconductor die 140, any package arrangement is possible. Moreover, in addition to the stacked semiconductor device 180 shown in FIG. 1, a semiconductor device such as a capacitor or an IPD (Integrated Passive Device) may sit on the semiconductor die 140, so that such a capacitor or an IPD may be electrically connected to the semiconductor die 140.

During assembly of a representative embodiment of the present invention, a stacked semiconductor device such as the stacked semiconductor device 180 may be set upon the semiconductor die 140 to electrically connect the stacked semiconductor device to the semiconductor die 140. A representative embodiment of the present invention permits one to prevent the loss of the stacked semiconductor device 180 in cases where the semiconductor die 140 is defective. For example, in some instances the cost of the stacked semiconductor device 180 may be relatively expensive compared with the cost of a relatively inexpensive semiconductor die 140. By first testing whether the relatively inexpensive semiconductor die 140 is defective, and then placing the relatively more expensive stacked semiconductor device 180 onto the semiconductor die 140, it may be determined whether the assembly is functional. In contrast, when the stacked semiconductor device 180 is assembled onto the semiconductor die 140, or the stacked semiconductor device 180 sits on the same plane as the semiconductor die 140 without testing the semiconductor die 140, if one of the semiconductor die is defective, both the stacked semiconductor device 180 and the semiconductor die 140 become useless and the cost of such devices is lost.

Thus, in a representative embodiment of the present invention, a semiconductor device such as the semiconductor device 100 of FIG. 1 may electrically connect the semiconductor die 140 and the stacked semiconductor device 180 sitting on the semiconductor die 140, via one or more structures such as the one or more conductive pillars 130, on the interposer 120. Once it is confirmed that the semiconductor die 140 is not defective, the stacked semiconductor device 180 may be placed so as to establish an electrical connection with the semiconductor die 140, and/or the substrate 110. Therefore, by employing a representative embodiment of the present invention, the cost of the semiconductor device 100 may be reduced.

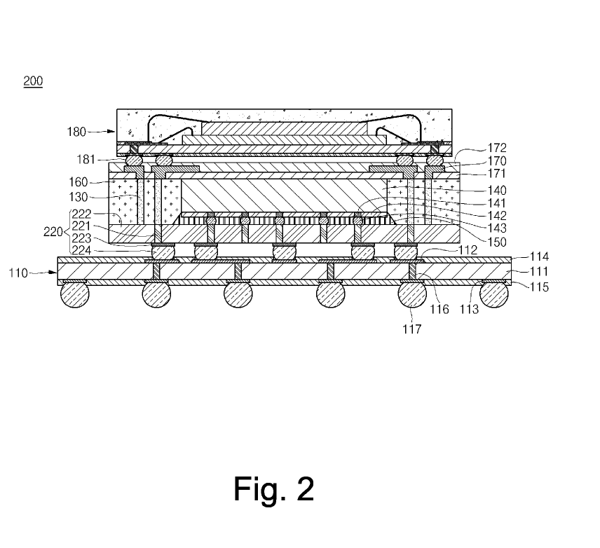

FIG. 2 is a sectional view of an exemplary semiconductor device 200, in accordance with another representative embodiment of the present invention.

The semiconductor device 200 shown in FIG. 2 is similar in many ways to the semiconductor device 100 shown in FIG. 1. Accordingly, the following discussion will focus primarily on the differences between the semiconductor device 100 of FIG. 1, and the semiconductor device 200 of FIG. 2.

Referring to FIG. 2, the semiconductor device 200 includes a substrate 110, an interposer 220, one or more conductive pillars 130, a semiconductor die 140, an underfill 150, an encapsulant 160, a redistribution layer 170, and a stacked semiconductor device 180.

In one representative embodiment of the present invention, the interposer 220 may be formed on the substrate 110, and may be electrically connected to the first circuit pattern 112 of the substrate 110. As shown in the example of FIG. 2, the interposer 220 includes a through electrode 221 and a dielectric layer 222. In some representative embodiments of the present invention, the dielectric layer 222 may be formed and then, one or more conductive paths such as the through electrode 221 may be formed, to penetrate the top and bottom of the dielectric layer 222. In such an embodiment, the through electrode 221 is exposed to the top and bottom surfaces of the dielectric layer 222. In addition, an under bump metal 223 may be formed on each of the through electrodes 221 exposed to the bottom of the interposer 220, and a bump 224 may be formed on the under bump metal 223, so that the interposer 220 may be electrically connected to the substrate 110. It should be noted that a greater or lesser number of through electrodes 221, under bump metal 223, and bump 224 may be employed without departing from the spirit and scope of the present invention.

In a representative embodiment of the present invention, the through electrode 221 may, for example, be formed of one selected from conductive materials such as Au, Ag and Cu, or equivalents or combinations thereof, or of any other suitable conductive material. Additionally, although shown separately in FIG. 2, an insulating material may be further formed between the dielectric layer 222 and the through electrode 221, in order to alleviate any stress resulting from a difference in thermal expansion coefficients of the dielectric layer 222 and the through electrode 221. In a representative embodiment of the present invention, the dielectric layer 222 may, for example, be formed of one selected from a silicon oxide layer, a silicon nitride layer, a polymer layer, and/or equivalents or combinations thereof, or any other suitable material.

Accordingly, the conductive pillar 130 is formed on the through electrode 221 exposed to the top of the interposer 220, and the semiconductor die 140 contacts the through electrode 221 exposed to the top of the interposer 220. That is, the one or more conductive pillars 130 may be formed on the through electrode 221 at one side or the edge of the interposer 220, and the semiconductor die 140 may contact the through electrode 221 at the middle of the interposer 220.

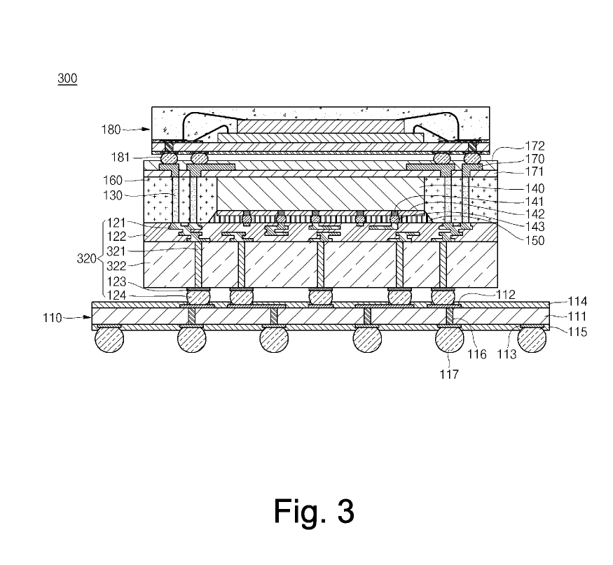

FIG. 3 is a sectional view of an exemplary semiconductor device 300, in accordance with yet another representative embodiment of the present invention.

The semiconductor device 300 shown in FIG. 3 is also similar in may ways to the semiconductor device 100 shown in FIG. 1. Accordingly, the following discussion will focus primarily on the differences between the example semiconductor device 100 of FIG. 1, and the example semiconductor device 300 illustrated in FIG. 3.

Referring now to FIG. 3, the exemplary semiconductor device 300 includes a substrate 110, an interposer 320, one or more conductive pillars 130, a semiconductor die 140, an underfill 150, an encapsulant 160, a redistribution layer 170, and a stacked semiconductor device 180.

The interposer 320 illustrated in FIG. 3 includes an internal redistribution layer 121, a through electrode 321, and a dummy substrate 322. In one representative embodiment of the present invention, the interposer 320 may include an internal redistribution layer 121 of a multi-layered structure that may be formed, and the internal redistribution layer 121 may be protected by a dielectric layer such as the dielectric layer 122. A substrate such as the dummy substrate 322 may then be formed on the bottom surface of a dielectric layer 122 and the through electrode 321 may be formed in the dummy substrate 322. As shown in the illustration of FIG. 3, the through electrode 321 may be formed so that it penetrates the dummy substrate 322, in order to be electrically connected to the internal redistribution layer 121. The dummy substrate 322 may be formed of the same material as the dielectric layer 122, or a different suitable material may be used. In accordance with a representative embodiment of the present invention, an under bump metal 123 may be formed on the through electrode 321 exposed at the bottom of the dummy substrate 322, and a bump 124 may be formed on the under bump metal 123, so that the interposer 320 may be electrically connected to the substrate 110.

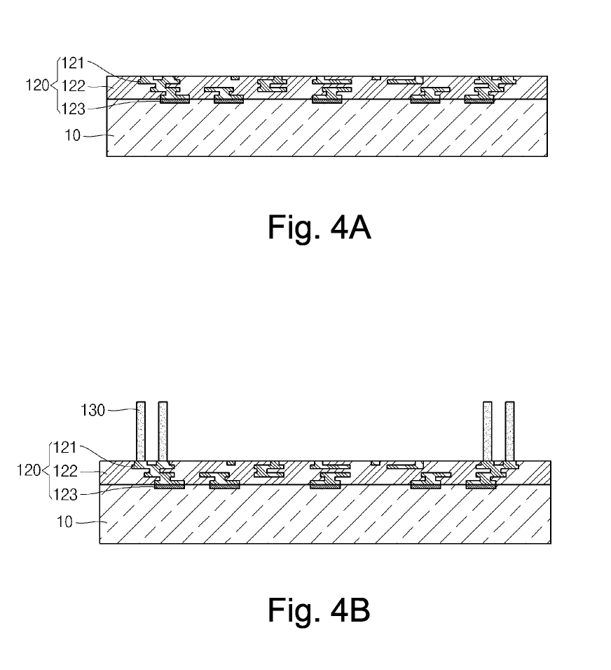

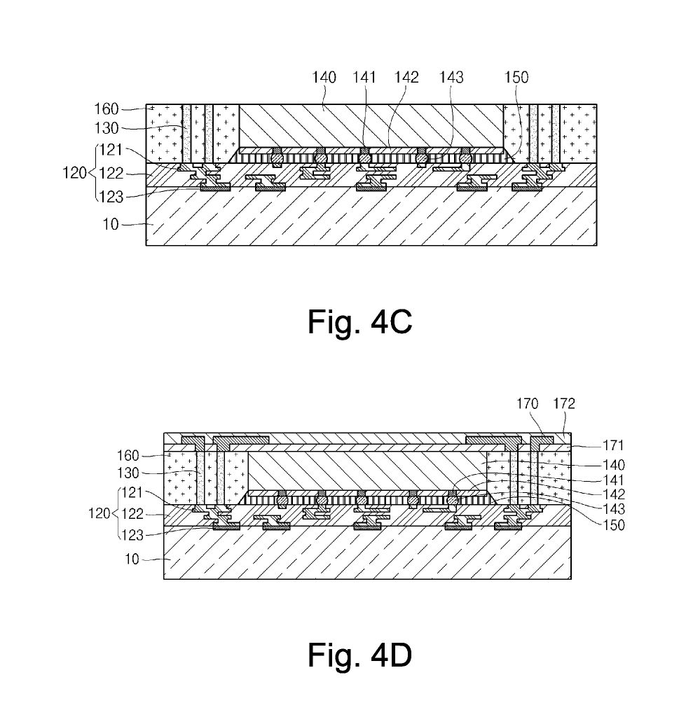

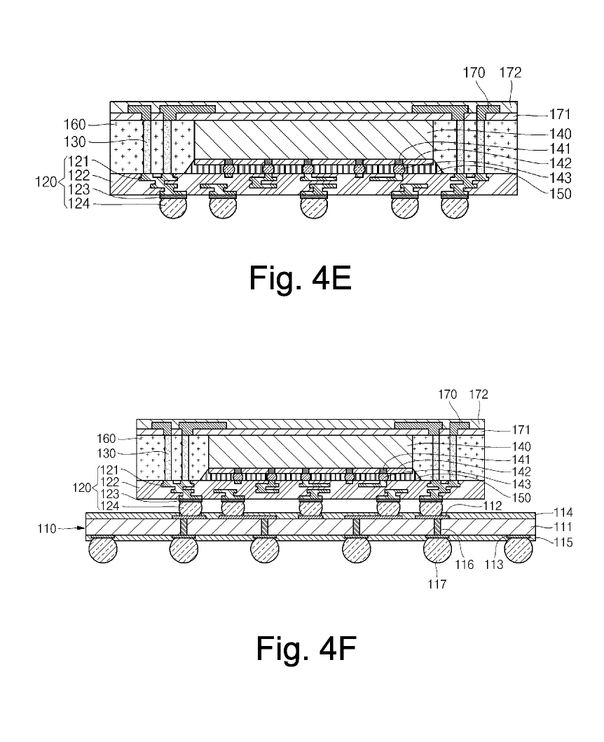

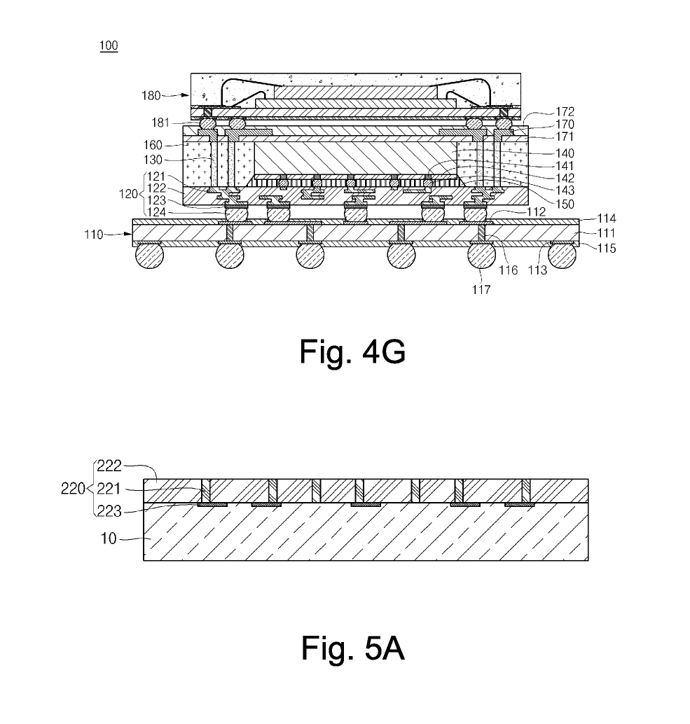

FIGS. 4A to 4G are sequential selection views illustrating an exemplary method of manufacturing a semiconductor device, in accordance with a representative embodiment of the present invention.

As shown in the illustrations of FIGS. 4A to 4G, one representative method of manufacturing a semiconductor device such as the exemplary semiconductor device 100 of FIG. 1, in accordance with a representative embodiment of the present invention includes, for example, in FIG. 4A, forming an interposer 120 on a dummy substrate 10; and in FIG. 4B, forming one or more conductive pillars 130 on the interposer 120. Additionally, such a method may include, as in FIG. 4C, contacting a semiconductor die 140 with the top surface of the interposer 120 and encapsulating the one or more conductive pillars 130 and the semiconductor die 140 with an encapsulant 160. The method may also include, as in FIG. 4D, forming a redistribution layer 170 on the semiconductor die 140 and, as shown in FIG. 4E, removing the dummy substrate 10. The method may further include, as in FIG. 4F, testing the semiconductor die 140 by contacting the interposer 120, which is contacted by the semiconductor die 140, with the top surface of a substrate 110 and, as shown in FIG. 4G, contacting a stacked semiconductor device 180 on the redistribution layer 170. This sequence of an exemplary method of manufacturing a semiconductor device in accordance with a representative embodiment of the present invention will be described in more detail as follows.

As shown in the illustration of FIG. 4A, the forming of the interposer 120 on the dummy substrate 10 may include directly forming the interposer 120 on the dummy substrate 100. In a representative embodiment of the present invention, an under bump metal 123 electrically connected to an internal redistribution layer 121 may be formed in advance on the dummy substrate 10. That is, after an under bump metal such as the under bump metal 123 of FIG. 4A is formed on the dummy substrate 10, and the internal redistribution layer 121 electrically connected to the under bump metal 123 is formed, the internal redistribution layer 121 may be covered by a dielectric layer 122. As mentioned above, the internal redistribution layer 121 may have a multi-layered structure, and may be formed with a relatively large width at the top and bottom surfaces of the dielectric layer 122. As shown in FIG. 4A, the internal redistribution layer 121 may, for example, be mainly formed of one selected from Cu, Al, and equivalents thereof, or any other suitable material, and the dielectric layer 122 may, for example, be formed of one selected from a silicon oxide layer, a silicon nitride layer, a polymer layer, and equivalents thereof, or any other suitable material. The dummy substrate 10 may, for example, be one of silicon, glass, and an equivalent thereof, but the present invention does not limit the types of materials used in the fabrication of the dummy substrate 10. It should be noted that the fabrication of a representative embodiment of the present invention is not necessarily limited to the materials mentioned above, and that other suitable materials may be employed without departing from the spirit and scope of the present invention.

As shown in the illustration of FIG. 4B, the forming of the one or more conductive pillars 130 on the interposer 120 may include forming the one or more conductive pillars 130 on the internal redistribution layer 121 exposed at the top surface of the interposer 120. The one or more conductive pillars 130 may be formed on the internal redistribution layer 121 at or near the edge of the interposer 120. As shown in FIG. 4B, the one or more conductive pillars 130 may be formed with the same height as that of the semiconductor die 140, so that the semiconductor die 140 may be electrically connected to the stacked semiconductor device 180 stacked on the semiconductor die 140. The one or more conductive pillars 130 may be formed of a copper pillar, but representative embodiments of the present invention are not necessarily limited to the use of copper. Instead, formation of such conductive pillars in a representative embodiment of the present invention may use any suitable material known now or in the future.

As shown in the illustration of FIG. 4C, in a representative embodiment of the present invention, the contact of the semiconductor die 140 with the top surface of the interposer 120 may include electrically interconnecting the interposer 120 with the semiconductor die 140. That is, because one or more bumps such as the bump 143 attached to the bond pad 141 of the semiconductor die 140 may be welded to the portion of the internal redistribution layer 121 exposed to the top surface of the interposer 120, the semiconductor die 140 is in electrical contact with the interposer 120. As shown in FIG. 4C, the semiconductor die 140 is then electrically interconnected with the internal redistribution layer 121 at the inside of the one or more conductive pillars 130. In addition, a suitable material may be used to form the underfill 150 between the interposer 120 and the semiconductor die 140. The underfill 150 may, for example, cover the lateral bottom surface area of the semiconductor die 140.

Still referring to FIG. 4C, it can be seen that the encapsulation of the one or more conductive pillars 130 and the semiconductor die 140 with the encapsulant 160 includes encapsulating the one or more conductive pillars 130 and the semiconductor die 140 on the interposer 120 with the encapsulant 160. That is, the one or more conductive pillars 130, the semiconductor die 140, and the underfill 150 on the interposer 120 may be covered by the encapsulant 160. As shown in FIG. 4C, the encapsulant 160 encapsulates the sides of the one or more conductive pillars 130 and the semiconductor die 140, leaving the top surfaces of those elements exposed.

As shown in the illustration of FIG. 4D, the fabrication of the redistribution layer 170 on the semiconductor die 140 includes forming the redistribution layer 170, which is electrically connected to the one or more conductive pillars 130. That is, the redistribution layer 170 is formed upon the top surface of the semiconductor die 140, and connects to the top surface of each of the one or more conductive pillars 130. As shown in FIG. 4D, after a lower passivation layer 171 that exposes the upper surface of each of the one or more conductive pillars 130 is formed on the semiconductor die 140, the redistribution layer 170 electrically connected to the one or more conductive pillars 130 is then formed. In accordance with a representative embodiment of the present invention, an upper passivation layer 172 may then be formed over the lower passivation layer 171 and the redistribution layer 170, in order to cover the redistribution layer 170. At this point, the upper passivation layer 172 exposes a portion of the redistribution layer 170, for example for subsequent connection to a stacked semiconductor device as illustrated in FIG. 4G.

Now making reference to FIG. 4E, a method in accordance with a representative embodiment of the present invention may include the removal of the dummy substrate 10, which may involve grinding and/or etching the dummy substrate 10 at the bottom of the interposer 120. Accordingly, the under bump metal 123 on the internal redistribution layer 121 exposed to the bottom of the interposer 120 is then exposed to the external environment by the grinding and/or etching of the dummy substrate 10. In addition, one or more conductive bumps such as the bump 124 may be formed in contact with the under bump metal 123. It should be noted that although a single interposer 120 and a single semiconductor are illustrated in FIGS. 4A-4G, this does not necessarily represent a specific limitation of the present invention, unless explicitly recited in the claims, and that representative embodiments of the present invention may be practiced by forming a plurality of interposers corresponding to a plurality of semiconductor die 140, where the plurality of interposers are formed on a wafer of which the plurality of semiconductor die are a part. In such an instance, after the removal of the dummy substrate 10, and/or formation of one or more bumps 124 on the under bump metal 123, the method of manufacture illustrated in FIGS. 4A-4G may include sawing (or singulating) the interposer 120. That is, because a plurality of semiconductor die 140 may be mounted in contact with the interposer 120, the sawing of the interposer 120 formed on the wafer may separate individual portions of the interposer 120 and a respective semiconductor die 140 (or a plurality of such semiconductor die 140).

As shown in the illustration of FIG. 4F, the testing of the semiconductor die 140 by establishing electrical contact with the interposer 120 (which is in electrical contact with the semiconductor die 140) with the substrate 110 includes establishing electrical contact of the interposer 120 (which includes the one or more conductive pillars 130, the semiconductor die 140, and the redistribution layer 170) with the substrate 110, and then testing the semiconductor die 140. That is, one or more bumps such as the bump 124 at the bottom of the interposer 120 establishes electrical contact with a first circuit pattern 112 at the top of the substrate 110, and the semiconductor die 140 may then be tested through the solder ball 117 formed (e.g., welded) at the bottom of the substrate 110 (using test equipment, not shown), to determine whether the semiconductor die 140 and any electrical interconnections are defective. If the semiconductor die 140 is determined to be defective, the above process may be repeated.

As shown in FIG. 4G, the establishing electrical contact of the stacked semiconductor device 180 with the redistribution layer 170 includes establishing electrical contact of the stacked semiconductor device 180 with the redistribution layer 170 that is electrically connected to the one or more conductive pillars 130. That is, the solder ball 181 of the stacked semiconductor device 180 is formed welded on the redistribution layer 170 that is exposed to the external environment through the upper passivation layer 172 so that the stacked semiconductor device 180 may electrically contact the redistribution layer 170. If it is determined that the semiconductor die 140 is normal, the stacked semiconductor device 180 is placed on the top of the assembly that includes the semiconductor die 140. More specifically, if the semiconductor die 140 is determined to be without defects and to operate normally, the stacked semiconductor device 180 may be electrically connected to the semiconductor die 140 and/or the substrate 110 through the redistribution layer 170, the conductive pillar 130, and the interposer 120. Furthermore, after the stacked semiconductor device 180 is stacked, the stacked semiconductor device 180 may be tested to determine whether the stacked semiconductor device 180 is defective. According to the exemplary method described above with respect to FIGS. 4A-4G, manufacture of a semiconductor device in accordance with a representative embodiment of the present invention, such as the semiconductor device 100 of FIG. 1, is then complete.

As mentioned above, after the semiconductor die 140 is tested to determine whether the semiconductor die 140 is defective, and the stacked semiconductor device 180 is stacked upon the semiconductor device 140, the loss of the stacked semiconductor device 180 due to a defect in the semiconductor die 140 may be prevented. However, when the stacked semiconductor device 180 is stacked upon the semiconductor die 140 and the stacked semiconductor device 180 is joined with the semiconductor die 140 without first testing the semiconductor die 140, if one of them is defective, both the stacked semiconductor device 180 and the semiconductor die 140 become useless.

That is, in a representative embodiment of a method of manufacture of the semiconductor device 100, the semiconductor die 140 in electrical contact with the top of the interposer 120 is tested first, in order to determine abnormality, and then the stacked semiconductor device 180 is stacked upon the semiconductor die 140. Therefore, the possible loss of the stacked semiconductor device 180 due to the occurrence of a defective semiconductor die such as the semiconductor die 140 may be prevented.

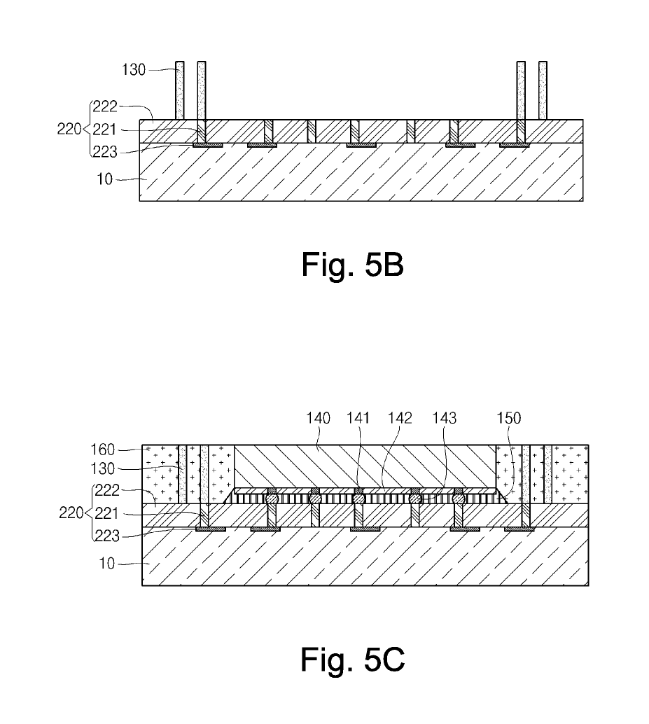

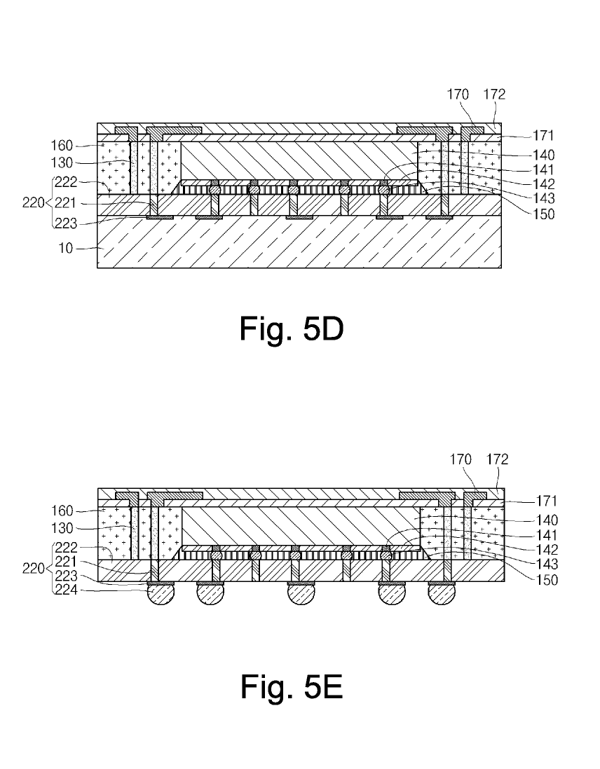

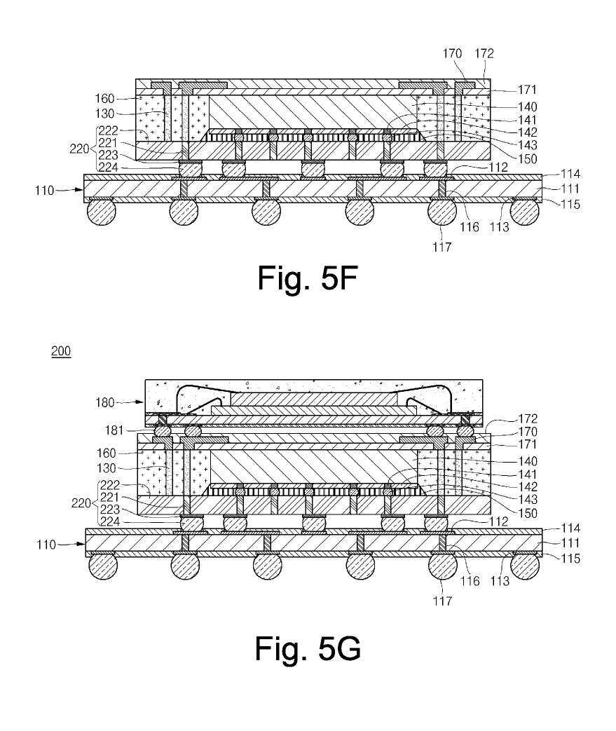

FIGS. 5A to 5G are sequential selection views illustrating an exemplary method of manufacturing a semiconductor device 100, in accordance with another representative embodiment of the present invention.

The method of manufacturing the semiconductor device 200 shown in FIGS. 5A to 5G is similar in many respects to that of manufacturing the semiconductor device 100 shown in the sequence of illustrations shown in FIG. 4A to FIG. 4G. However, the method of manufacturing the semiconductor device 200 shown in FIGS. 5A to 5G illustrate a different method of forming the interposer 220 on the dummy substrate 10. Accordingly, the forming of the interposer 220 on the dummy substrate 10, the forming of the one or more conductive pillars 130 on the interposer 220, and the contacting of the semiconductor die 140 with the top of the interposer 220 will be described.

As shown in FIG. 5A, the forming of the interposer 220 on the dummy substrate 10 in accordance with a representative embodiment of the present invention may include directly forming the interposer 220 on the dummy substrate 10. As shown in FIG. 5A, an under bump metal 223 electrically connected via electrode 221 may be formed in advance on the dummy substrate 220. That is, after the under bump metal 223 is formed on the dummy substrate 10, and a dielectric layer 222 is formed on the dummy substrate 10, the through electrode 221 penetrating from the top surface of the dielectric layer 222 to its bottom surface and electrically connected to the under bump metal 223 is formed. In a representative embodiment of the present invention, a through electrode such as the through electrode 221 may be formed of one selected from conductive materials such as Au, Ag and Cu or a combination thereof, or of any other suitable material. Additionally, the dielectric layer 222 may be formed of one or more selected from a silicon oxide layer, a silicon nitride layer, a polymer layer, and equivalents thereof. It should be noted that the use of the above materials in the formation of the through electrode 221 and the dielectric layer 222 are not necessarily specific limitations of the present invention, unless explicitly recited in the claims, and that any suitable materials may be employed. Additionally, an insulating material (not shown) may be further formed between the dielectric layer 222 and the through electrode 221, in order to alleviate any stress that may result from a difference in the thermal expansion coefficient of the material of the dielectric layer 222 and the material of the through electrode 221.

As shown in the illustration of FIG. 5B, the forming of the one or more conductive pillars 130 on the interposer 220 in a manner in accordance with a representative embodiment of the present invention may include forming the one or more conductive pillars 130 on the through electrode 221 exposed at the top of the interposer 220. The one or more conductive pillars 130 may, for example, be formed on the through electrode 221 at or near the edge of the interposer 221. As shown in FIG. 5B, the one or more conductive pillars 130 may be formed with the same height as the semiconductor die 140, so that the semiconductor die 140 may be electrically connected to the stacked semiconductor device 180 stacked on the semiconductor die 140. The one or more conductive pillars 130 may be formed of a copper pillar, but use of this material does not necessarily represent a specific limitation of the present invention, unless explicitly recited in the claims.

As shown in FIG. 5C, in a representative embodiment of the present invention, contact of the semiconductor die 140 with the top surface of the interposer 220 includes establishing electrical contact between the interposer 220 and the semiconductor die 140. That is, because the bump 143 attached to the bond pad 141 of the semiconductor die 140 is formed (e.g., welded) on the through electrode 221 exposed at the top of the interposer 221, the semiconductor die 140 electrically contacts the interposer 220. In the illustration of FIG. 5C, the semiconductor die 140 electrically contacts the through electrode 221 at or near the inside of the one or more conductive pillars 130. Furthermore, an underfill shown as the underfill 150 is formed between the interposer 220 and the semiconductor die 140. In a representative embodiment of the present invention, the underfill 150 may cover the lateral bottom area of the semiconductor die 140.

According to a representative embodiment of the present invention, in relation to a semiconductor device and a method of manufacturing the same, a semiconductor die contacting the top of an interposer is tested first in order to determine abnormality and then, a stacked semiconductor device is stacked on the semiconductor die. Therefore, the loss of the stacked semiconductor device due to a defective underlying semiconductor die may be prevented.

An aspect of the present invention provides a semiconductor device including a plurality of semiconductor dies, which reduces costs by preventing the loss of other semiconductor die due to one defective semiconductor die, and a method of manufacturing the semiconductor device. According to at least one of the embodiments, a method of manufacturing a semiconductor device may comprise forming an interposer on a dummy substrate; forming a conductive pillar on the interposer; contacting the top of the interposer with at least one semiconductor die; and encapsulating the conductive pillar and the at least one semiconductor die with an encapsulant. Such a method may also comprise forming a redistribution layer, which is electrically connected to the conductive pillar, on the at least one semiconductor die; removing the dummy substrate from the interposer; attaching the interposer, which has the at least one semiconductor die in contact, to a substrate and testing the at least one semiconductor die; and contacting a stacked semiconductor device with the redistribution layer.

In a representative embodiment of the present invention, the interposer may comprise an internal redistribution layer and a dielectric layer, and the conductive pillar may be formed on a portion of the internal wiring layer exposed at the top of the interposer. The at least one semiconductor die may be electrically connected to the internal redistribution layer exposed at the top of the interposer, and the forming of the interposer may comprise forming an under bump metal, which is electrically connected to the internal redistribution layer exposed at the bottom of the interposer, in advance on the dummy substrate. The removing of the dummy substrate may comprise removing the dummy substrate through one or both of grinding and etching to expose the under bump metal, and after the removing of the dummy substrate, a bump may contact the under bump metal and the interposer may be electrically connected to the substrate through the bump. The interposer may include a through electrode and a dielectric layer, and the conductive pillar may be formed on a portion of the through electrode exposed at the top of the interposer.

The at least one semiconductor die may be electrically connected to the through electrode exposed at the top of the interposer. The forming of the interposer may include forming a under bump metal, which is electrically connected to the through electrode exposed at the bottom of the interposer, in advance on the dummy substrate. The removing of the dummy substrate may include removing the dummy substrate through one or both of grinding and etching to expose the under bump metal, and after the removing of the dummy substrate, a bump may be attached to the under bump metal and the interposer may be electrically connected to the substrate through the bump. After the removing of the dummy substrate, the method may further comprise sawing the interposer.

In such a representative embodiment of the present invention, the conductive pillar may be formed at the outside of the semiconductor die (e.g., in a region around the perimeter of the semiconductor die 140 location), and may be formed with the same height as the semiconductor die. The encapsulant may encapsulate the conductive pillar and the at least one semiconductor die to expose the tops thereof. After the attaching of the at least one semiconductor die, an underfill may be filled between the semiconductor die and the interposer, and the testing of the semiconductor die may include testing the semiconductor die through the substrate. After the contacting of the stacked semiconductor device, the method may further include testing the stacked semiconductor device (and/or the entire assembly).

Additional aspects of the present invention may be seen in a method of manufacturing a semiconductor device that comprises forming an interposer, which includes an internal redistribution layer and a dielectric layer, on a dummy substrate; and forming a through electrode, which is electrically connected to the internal redistribution layer, on the dummy substrate. Such a method may also comprise forming a conductive pillar on the interposer; contacting the top of the interposer with at least one semiconductor die; and encapsulating the conductive pillar and the at least one semiconductor die with an encapsulant. A method in accordance with the present invention may comprise forming a redistribution layer that is electrically connected to the conductive pillar, on the at least one semiconductor die; attaching the interposer, which has the at least one semiconductor die in contact, to a substrate and testing the at least one semiconductor die; and contacting the redistribution layer with a stacked semiconductor device. After the forming of the redistribution layer, the method may further comprise one or both of grinding and etching the dummy substrate to expose the through electrode and forming a bump on the through electrode. After the forming of the bump, the method may further include sawing the interposer.

Additional aspects of the present invention may be seen in a semiconductor device that comprises a substrate; an interposer contacting the top of the interposer; a conductive pillar disposed on the top of the interposer; at least one semiconductor die contacting the top of the interposer; an encapsulant encapsulating the conductive pillar and the at least one semiconductor die; a redistribution layer disposed on the encapsulant and electrically connected to the conductive pillar; and a stacked semiconductor device contacting the redistribution layer. The interposer may include an internal redistribution layer and a dielectric layer. The conductive pillar may be formed on a portion of the internal redistribution layer exposed at the top of the interposer. The semiconductor die may be placed at the inside of the conductive pillar and may be electrically connected to the internal redistribution layer exposed at the top of the interposer.

In such a device, the interposer may include a through electrode and a dielectric layer. The conductive pillar may be formed on a portion of the through electrode exposed at the top of the interposer. The at least one semiconductor die may be disposed at the inside of the conductive pillar (e.g., at a region of the interposer different from the conductive pillar, between conductive pillars, within a perimeter of conductive pillars, etc.) and may be electrically connected to the through electrode exposed at the top of the interposer. The encapsulant may expose the tops of the conductive pillar and the at least one semiconductor die, and an underfill may be filled between the semiconductor die and the interposer. Further, the conductive pillar may have the same height as the semiconductor die.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A semiconductor device comprising:
a substrate;
an interposer electrically contacting a top surface of the substrate;
a conductive pillar disposed on a top surface of the interposer;
a semiconductor die electrically contacting a top surface of the interposer;
an encapsulant encapsulating the conductive pillar and the semiconductor die;
a redistribution layer disposed over the encapsulant and electrically connected to the conductive pillar; and
a stacked semiconductor device electrically contacting the redistribution layer.

2. The device as claimed in claim 1, wherein the interposer comprises an internal redistribution layer and a dielectric layer.

3. The device as claimed in claim 2, wherein the conductive pillar is formed on a portion of the internal redistribution layer exposed at the top of the interposer.

4. The device as claimed in claim 2, wherein the semiconductor die is positioned over the interposer at a location beside the conductive pillar and is electrically connected to a portion of the internal redistribution layer exposed at the top of the interposer.

5. The device as claimed in claim 1, wherein the semiconductor die is positioned over the interposer at a location between the conductive pillar and another conductive pillar.

6. The device as claimed in claim 1, wherein the interposer comprises a through electrode and a dielectric layer.

7. The device as claimed in claim 6, wherein the conductive pillar is formed on a portion of the through electrode exposed at the top of the interposer.

8. The device as claimed in claim 7, wherein the semiconductor die is positioned over the interposer at a location beside the conductive pillar and is electrically connected to a portion of the through electrode exposed at the top of the interposer.

9. The device as claimed in claim 1, wherein the encapsulant exposes at least a portion of a top surface of the conductive pillar and at least a portion of a top surface of the semiconductor die.

10. The device as claimed in claim 9, wherein the redistribution layer comprises a passivation layer contacting a top surface of the encapsulant and exposing at least a portion of the top surface of the conductive pillar and at least a portion of the top surface of the semiconductor die.

11. The device as claimed in claim 1, wherein the interposer electrically contacts the top of the substrate through at least a dummy substrate.

12. The device as claimed in claim 1, wherein a subassembly of the device that comprises the interposer, the conductive pillar, the semiconductor die, the encapsulant, and the redistribution layer is a pretested subassembly that is tested prior to the stacked semiconductor device electrically contacting the redistribution layer.

13. The device as claimed in claim 12, wherein the conductive pillar has generally a same height above the interposer as the semiconductor die.

14. A method of manufacturing a semiconductor device, the method comprising:
forming an interposer on a dummy substrate;
forming a conductive pillar on the interposer;
electrically contacting a top surface of the interposer with a semiconductor die;
encapsulating the conductive pillar and the semiconductor die with an encapsulant;
forming a redistribution layer over the encapsulant that is electrically connected to the conductive pillar;
removing the dummy substrate from the interposer; and
electrically contacting a stacked semiconductor device to the redistribution layer.

15. The method as claimed in claim 14, wherein said forming an interposer comprises forming an interposer that comprises an internal redistribution layer and a dielectric layer.

16. The method as claimed in claim 14, wherein said forming an interposer comprises forming an interposer that comprises a through electrode and a dielectric layer.

17. The method as claimed in claim 14, comprising positioning the semiconductor die over the interposer at a location between the formed conductive pillar and another formed conductive pillar.

18. The method as claimed in claim 14, wherein said encapsulating comprises leaving exposed at least a portion of a top surface of the conductive pillar and at least a portion of a top surface of the semiconductor die.

19. The device as claimed in claim 14, wherein said forming a conductive pillar comprises forming the conductive pillar to have generally a same height above the interposer as the semiconductor die.

20. A method of manufacturing a semiconductor device, the method comprising:
forming a subassembly comprising:
forming an interposer on a dummy substrate;
forming a conductive pillar on the interposer;
electrically contacting a top of the interposer with a semiconductor die;
encapsulating the conductive pillar and the semiconductor die with an encapsulant; and
forming a redistribution layer over the encapsulant that is electrically connected to the conductive pillar; and
removing the dummy substrate from the interposer;
testing the subassembly; and
after said testing, electrically contacting a stacked semiconductor device with the redistribution layer.
